(19) United States
(12) Patent Application Publication
(10) Pub. No.: US 2025/0301913 A1
(43) Pub. Date: Sep. 25, 2025

(54) SEMICONDUCTOR DEVICE

(71) Applicant: FUJI ELECTRIC CO., LTD., Kawasaki-shi (JP)

(72) Inventors: Shinichiro ADACHI, Matsumoto-city (JP); Tadahiko SATO, Matsumoto-city (JP)

(73) Assignee: FUJI ELECTRIC CO., LTD., Kawasaki-shi (JP)

(21) Appl. No.: 19/064,462

(22) Filed: Feb. 26, 2025

(30) Foreign Application Priority Data
Mar. 22, 2024 (JP) 2024-046525

(51) Int. Cl. H10N 50/10; H01L 23/04; H01L 23/495; H01L 23/552

(52) U.S. Cl. CPC H10N 50/10; H01L 23/041; H01L 23/49517; H01L 23/552

(57) ABSTRACT

A semiconductor device, including: a conductive plate; a case which includes: a frame, which surrounds a housing area that houses the conductive plate with a main surface of the conductive plate facing upward, and an external terminal provided on the frame, the external terminal including a wiring portion that extends from a part of the frame to the housing area, and an end portion that is integrally connected to the wiring portion and is bonded to the conductive plate; and a detection element provided facing an upper surface of the wiring portion of the external terminal with a gap in between.

### CROSS-REFERENCE TO RELATED APPLICATION

This application is based upon and claims the benefit of priority of the prior Japanese Patent Application No. 2024-046525, filed on Mar. 22, 2024, the entire contents of which are incorporated herein by reference.

### BACKGROUND OF THE INVENTION

### 1. Field of the Invention

The embodiment discussed herein relates to a semiconductor device.

### 2. Background of the Related Art

Semiconductor devices include various types of sensors for detecting various properties (see for example, International Publication Pamphlet No. WO 2021/151949). As one example, a semiconductor device includes a sensor that detects an output current (see for example, Japanese Laid-open Patent Publication Nos. 2018-121418 and 2017-168721.

### SUMMARY OF THE INVENTION

According to an aspect of the present disclosure, there is provided a semiconductor device including: a conductive plate; a case which includes a frame, which surrounds a housing area that houses the conductive plate with a main surface of the conductive plate facing upward, and an external terminal provided on the frame, the external terminal including a wiring portion that extends from a part of the frame to the housing area, and an end portion that is integrally connected to the wiring portion and is bonded to the conductive plate; and a detection element provided facing an upper surface of the wiring portion of the external terminal with a gap in between.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to an embodiment;

FIG. 2 is a plan view of the semiconductor device according to the embodiment (with a housing cover removed);

FIG. 3 is a side view of the semiconductor device according to the embodiment;

FIG. 4 is a plan view of a semiconductor unit included in the semiconductor device according to the embodiment;

FIG. 5 is a cross-sectional view of a semiconductor unit included in the semiconductor device according to the embodiment;

FIG. 6 is a cross-sectional view (in a short-side direction) of the semiconductor device according to the embodiment;

FIG. 7 is a cross-sectional view (in a long-side direction) of the semiconductor device according to the embodiment; and

FIG. 8 is a plan view of a principal part of the semiconductor device according to the embodiment.

### DETAILED DESCRIPTION OF THE INVENTION

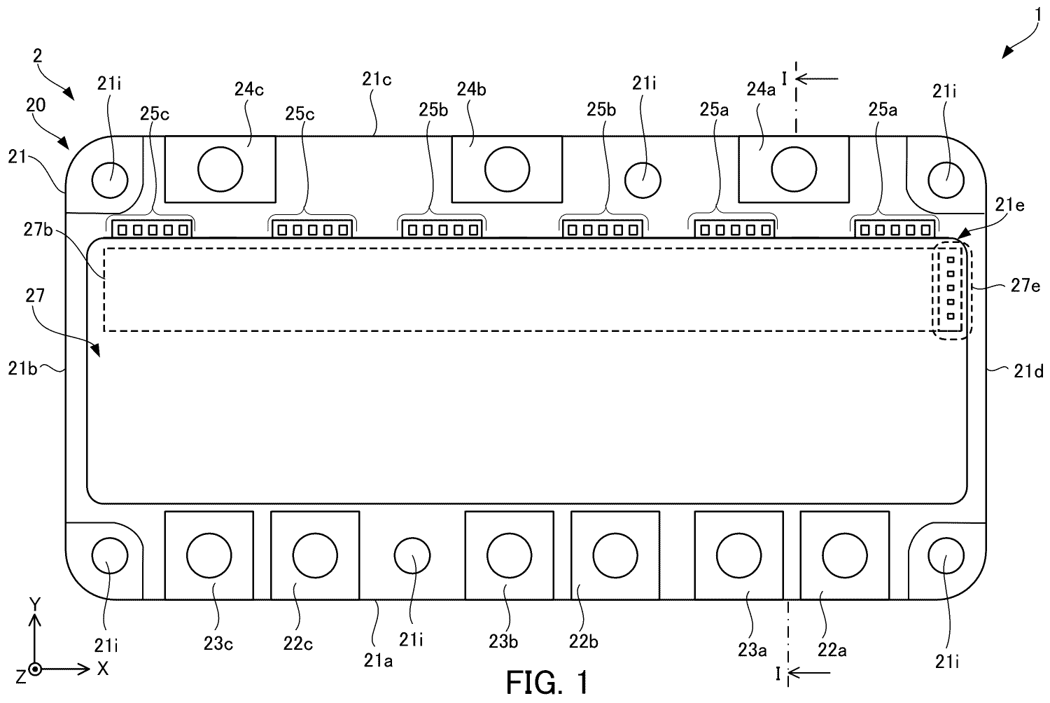

An embodiment will be described below with reference to the accompanying drawings. Note that in the following description, the expressions “front surface” and “upper surface” refer to an X-Y plane that faces upward (in the “+Z direction”) for a semiconductor device 1 depicted in FIG. 1. In the same way, the expression “up” refers to the upward direction (or “+Z direction”) for the semiconductor device 1 in FIG. 1. The expressions “rear surface” and “lower surface” refer to an X-Y plane that faces downward (that is, in the “−Z direction”) for the semiconductor device 1 depicted in FIG. 1. In the same way, the expression “down” refers to the downward direction (or “−Z direction”) for the semiconductor device 1 depicted in FIG. 1. These expressions are used as needed to refer to the same directions as above in the other drawings. The expressions “high” and “above” refer to upper (that is, “+Z direction”) positions for the semiconductor device 1 in FIG. 1. In the same way, the expressions “low” and “below” refer to lower (that is, “−Z direction”) positions for the semiconductor device 1 in FIG. 1. The expressions “front surface”, “upper surface”, “up”, “rear surface”, “lower surface”, “down”, and “side surface” are merely convenient expressions used to specify relative positional relationships, and are not intended to limit the technical scope of the present disclosure. As one example, “up” and “down” do not necessarily mean directions that are perpendicular to the ground. That is, the “up” and “down” directions are not limited to the direction of gravity. Additionally, in the following description, the expression “main component” refers to a component contained at a volume ratio of 80% or more. The expression “substantially equal” may refer to a range that is within ±10%. Likewise, “vertical”, “perpendicular”, and “parallel” may refer to ranges of within ±10° inclusive of such directions.

### Embodiment

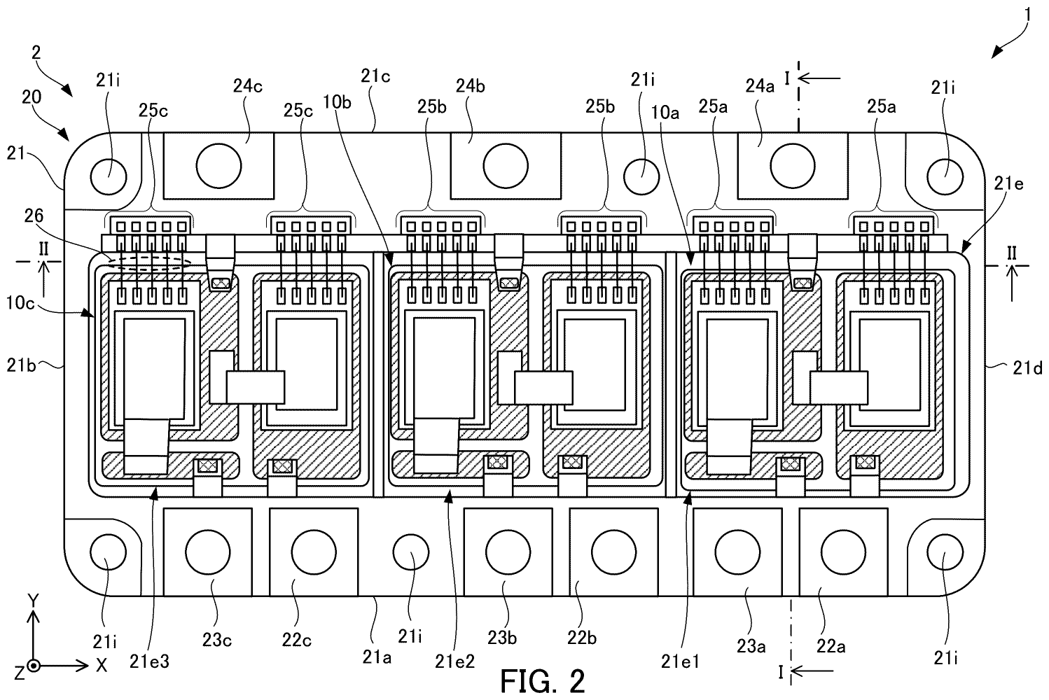

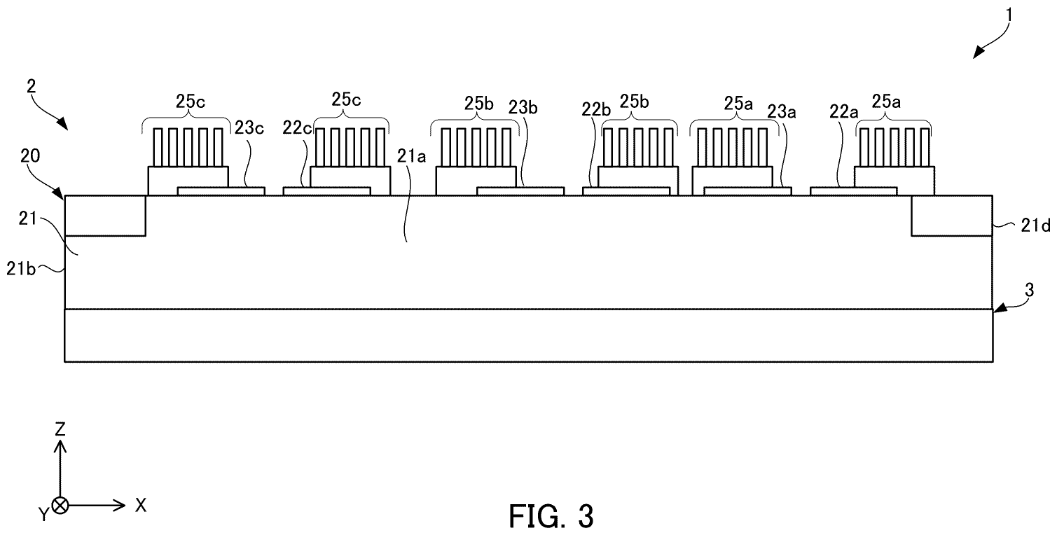

A semiconductor device 1 according to an embodiment will now be described with reference to FIGS. 1 to 3. FIG. 1 is a plan view of a semiconductor device according to an embodiment, and FIG. 2 is a plan view of the semiconductor device according to the embodiment (with a housing cover removed). FIG. 3 is a side view of the semiconductor device according to the embodiment. Note that FIG. 2 is a plan view of FIG. 1 in a state where a housing cover 27 has been removed. A sealing member is also omitted from FIG. 2. FIG. 3 is a side view of FIG. 1 and FIG. 2, when looking at the X-Z plane in the +Y direction.

The semiconductor device 1 includes a semiconductor module 2 and a cooling module 3. The semiconductor module 2 includes semiconductor units 10a, 10b, and 10c and a case 20 that houses the semiconductor units 10a, 10b, and 10c. The semiconductor units 10a, 10b, and 10c housed in the case 20 are sealed by a sealing member 29, described later.

Note that the semiconductor units 10a, 10b, and 10c all have the same configuration. When not distinguishing between them, the semiconductor units 10a, 10b, and 10c are collectively referred to as the “semiconductor units 10”. The semiconductor units 10 will be described in detail later.

First, the case 20 includes a frame 21, first connection terminals 22a, 22b, and 22c, second connection terminals 23a, 23b, and 23c, a W-phase output terminal 24a, a V-phase output terminal 24b, a U-phase output terminal 24c (examples of “external terminal”), and control terminals 25a, 25b, and 25c. The case 20 also includes the housing cover 27.

The frame 21 is substantially rectangular in shape in plan view, and is surrounded on four sides by outer walls 21a, 21b, 21c, and 21d. Note that the outer walls 21a and 21c extend in the long-side direction corresponding to the longer edges of the frame 21, and the outer walls 21b and 21d extend in the short-side direction corresponding to the shorter edges of the frame 21. Corners where the outer walls 21a, 21b, 21c, and 21d are joined do not need to be right-angled. and as depicted in FIG. 1 and FIG. 2, the joins between the side walls may be rounded. Through holes 21i that pass through the frame 21 are formed in the corners of the front surface of the frame 21. Note that the through holes 21i formed in the corners of the frame 21 may be formed so as to be positioned lower than the front surface of the frame 21.

The frame 21 surrounds an opening 21e on all four sides. The opening 21e is rectangular in shape in plan view, and is an opening that extends from the upper surface to the lower surface of the frame 21. The frame 21 further includes unit housing portions 21e1, 21e2, and 21e3 (housing area) within the opening 21e. These unit housing portions 21e1, 21e2, and 21e3 are provided in the opening 21e in order along the outer walls 21a and 21c. A step may be provided on the inner wall of the unit housing portions 21e1, 21e2, and 21e3 on the outer wall 21c side. This step will be described later. The unit housing portions 21e1, 21e2, and 21e3 house the semiconductor units 10a, 10b, and 10c, respectively.

Note that the semiconductor units 10a, 10b, and 10c are each joined to a top plate (not illustrated) of the cooling module 3. When the frame 21 is attached to the top plate of the cooling module 3, the semiconductor units 10a, 10b, and 10c become housed in the unit housing portions 21e1, 21e2, 21e3 respectively of the frame 21. The frame 21 is attached to the top plate of the cooling module 3 using adhesive.

In plan view, the frame 21 is provided with first connection terminals 22a, 22b, and 22c and second connection terminals 23a, 23b, and 23c on an upper surface on the outer wall 21a side. An outer end portion at one end of each of first connection terminals 22a, 22b, and 22c and the second connection terminals 23a, 23b, and 23c is disposed on the upper surface on the outer wall 21a side. Note that an opening may be formed in each of these outer end portions. Nuts may be housed in the upper surface of the frame 21 where these outer end portions are disposed so as to face the openings in the outer end portions. Inner end portions at the other ends of the terminals are exposed inside the unit housing portions 21e1, 21e2, and 21e3 and are electrically connected to the semiconductor units 10a, 10b, and 10c. Intermediate parts of the first connection terminals 22a, 22b, and 22c and the second connection terminals 23a, 23b, and 23c between the outer end portions and the inner end portions are provided inside the frame 21.

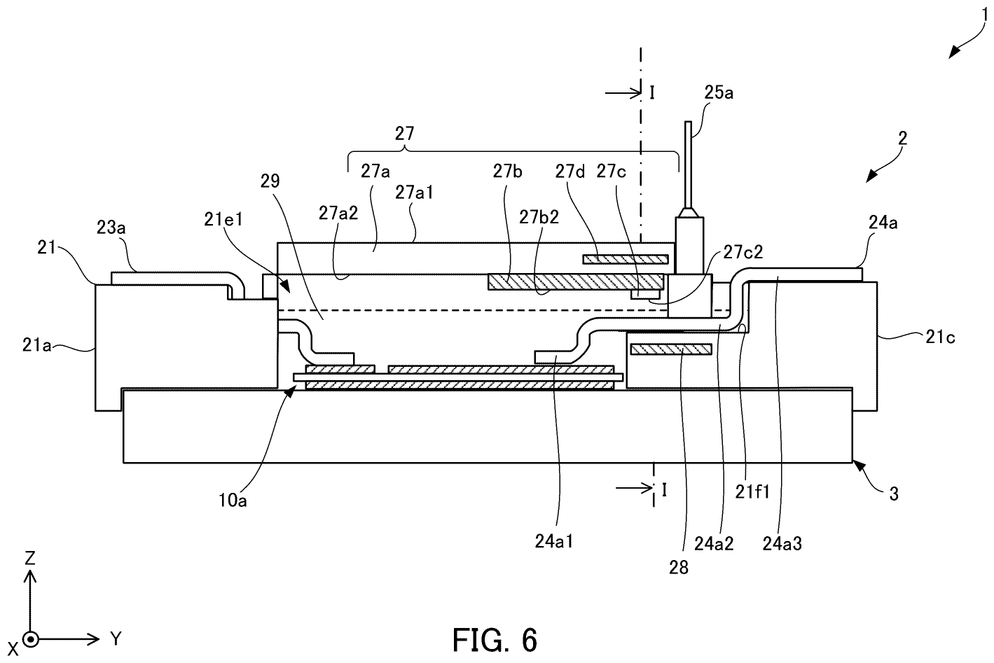

In plan view, the frame 21 is provided with the W-phase output terminal 24a, the V-phase output terminal 24b, and the U-phase output terminal 24c on the outer wall 21c side. One end, or “outer end portion” or “external connecting portion”, of each of the W-phase output terminal 24a, the V-phase output terminal 24b, and the U-phase output terminal 24c is disposed on the upper surface of the outer wall 21c side of the frame 21. Note that an opening may be formed in each of these outer end portions. Nuts may be housed in the upper surface of the frame 21 where these outer end portions are disposed so as to face the openings in the outer end portions. Inner end portions (internal joining portions) at the other ends of the terminals are exposed inside the unit housing portions 21e1, 21e2, and 21e3 and are electrically connected to the semiconductor units 10a, 10b, and 10c. Intermediate parts (wiring portion) of the W-phase output terminal 24a, the V-phase output terminal 24b, and the U-phase output terminal 24c between the outer end portions and the inner end portions are provided inside the frame 21. As one example, as depicted in FIG. 6 described later, the W-phase output terminal 24a integrally includes an internal joining portion 24a1, a wiring portion 24a2, and an external connecting portion 24a3. As one example, the wiring portion 24a2 is attached to the frame 21 so as to be parallel to the upper surface of an insulated circuit board 11 that is housed.

Accordingly, in plan view, the frame 21 includes the first connection terminal 22a and the second connection terminal 23a on the upper surface of the outer wall 21a side and the W-phase output terminal 24a on the upper surface of the outer wall 21c side, with the unit housing portion 21e1 in between. In the same way, in plan view, the frame 21 includes the first connection terminal 22b and the second connection terminal 23b on the upper surface of the outer wall 21a side and the V-phase output terminal 24b on the upper surface of the outer wall 21c side, with the unit housing portion 21e2 in between. In addition, in plan view, the frame 21 includes the first connection terminal 22c and the second connection terminal 23c on the upper surface of the outer wall 21a side and the U-phase output terminal 24c on the upper surface of the outer wall 21c side, with the unit housing portion 21e3 in between.

Note that the frame 21 includes a lower shielding plate corresponding to the inner end portions of the W-phase output terminal 24a, the V-phase output terminal 24b, and the U-phase output terminal 24c. The inner end portions of the W-phase output terminal 24a, the V-phase output terminal 24b, and the U-phase output terminal 24c and the lower shielding plate will be described in detail later.

In plan view, the frame 21 further includes control terminals 25a, 25b, and 25c along the outer wall 21c on the upper surface of the outer wall 21c sides of the unit housing portions 21e1, 21e2, and 21e3. Each of the control terminals 25a, 25b, and 25c may be provided by being split in two. When doing so, the control terminals 25a, 25b, and 25c may be provided inward of and on both sides of the W-phase output terminal 24a, the V-phase output terminal 24b, and the U-phase output terminal 24c. The outer end portions of the control terminals 25a, 25b, and 25c extend vertically upward (that is, in the +Z direction) from the upper surface of the outer wall 21c side of the frame 21. Inner end portions of the control terminals 25a, 25b, and 25c are exposed facing upward (in the +Z direction) on the outer wall 21c side of the unit housing portions 21e1, 21e2, and 21e3.

The first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c are all made of a metal with superior electrical conductivity. Example metals include copper, aluminum, or an alloy containing at least one of these metals as a main component. The surfaces of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c may be plated. When doing so, example plating materials used here include nickel, nickel-phosphorus alloy, and nickel-boron alloy.

The frame 21 includes the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c, and is integrally molded by injection molding using a thermoplastic resin. When doing so, the lower shielding plate, described later, may also be integrally molded. Example thermoplastic resins include polyphenylene sulfide resin, polybutylene terephthalate resin, polybutylene succinate resin, polyamide resin, and acrylonitrile butadiene styrene resin.

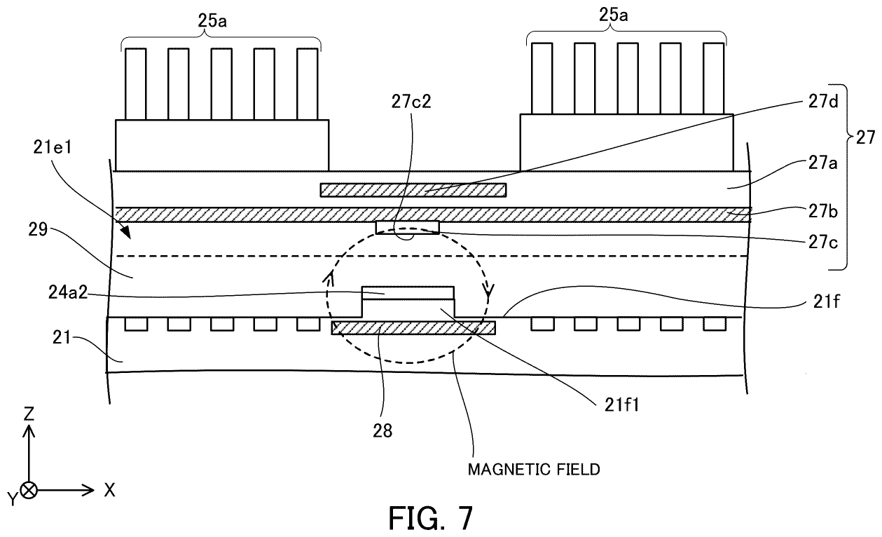

The sealing member 29 (see, for example, FIGS. 6 and 7) that seals the unit housing portions 21e1, 21e2, and 21e3 of the frame 21 is preferably made of silicone gel. Alternatively, the resin may be a thermosetting resin, such as an epoxy resin, a phenol resin, a maleimide resin, or a polyester resin. It is sufficient for the sealing member 29 to entirely seal the semiconductor units 10a, 10b, and 10c housed in the unit housing portions 21e1, 21e2, and 21e3, with no need to seal the entire unit housing portions 21e1, 21e2, and 21e3. It is desirable for parts of wires 26, the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c that are exposed in the unit housing portions 21e1, 21e2, and 21e3 to be sealed.

The housing cover 27 is formed in a shape that matches the opening 21e in the frame 21 in plan view, and is attached to the opening 21e in the frame 21. The housing cover 27 may include a detection element, a wiring board, an upper shielding plate, and a detection output terminal 27e corresponding to each of the W-phase output terminal 24a, the V-phase output terminal 24b, and the U-phase output terminal 24c. The housing cover 27 may be formed by injection molding using the same material as the frame 21. The housing cover 27 may be integrally molded to include the upper shielding plate(s). The housing cover 27 is described in detail later. Note that in FIG. 1, the position of a wiring board 27b, described later, included on an inner surface side of the housing cover 27 is indicated by a broken line.

The cooling module 3 includes a top plate, not illustrated, on whose upper surface the semiconductor module 2 is placed. In more detail, as described above, the frame 21 is attached to the top plate of the cooling module 3 on which the semiconductor units 10a, 10b, and 10c are disposed. The top plate is wider than a rear surface of the semiconductor module 2 and is flat. As one example, the cooling module 3 is a heat dissipation base provided with heat dissipation fins, or a cooling apparatus with refrigerant circulating inside.

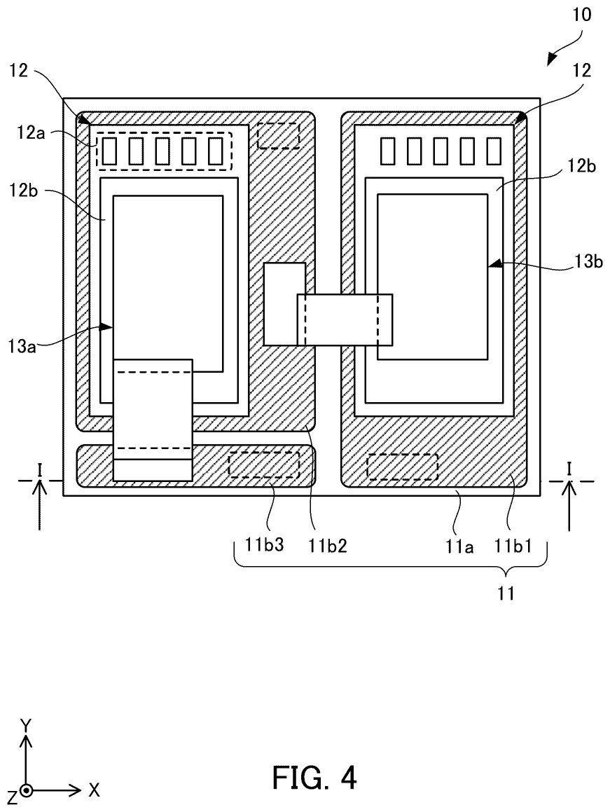

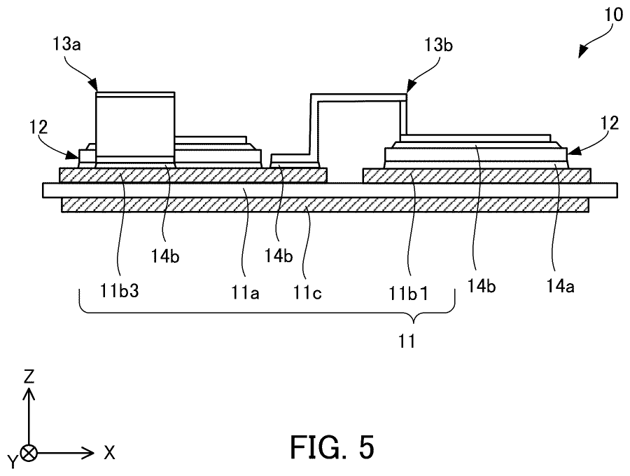

Next, the semiconductor units 10a, 10b, and 10c will be described with reference to FIGS. 4 and 5. FIG. 4 is a plan view of a semiconductor unit included in the semiconductor device according to the embodiment. FIG. 5 is a cross-sectional view of a semiconductor unit included in the semiconductor device according to the embodiment. Note that FIG. 5 is a cross-sectional view taken along the dash-dotted line I-I in FIG. 4.

Each semiconductor unit 10 may be a device that constructs a one-phase inverter circuit. A semiconductor unit 10 includes an insulated circuit board 11, two semiconductor chips 12, and lead frames 13a and 13b. The semiconductor chips 12 are bonded to the insulated circuit board 11 by a bonding member 14a. The lead frames 13a and 13b are bonded to the main electrodes on the upper surface of the semiconductor chip 12 and to the upper surface of the insulated circuit board 11 by a bonding member 14b. Note that the lead frames 13a and 13b may be bonded to the insulated circuit board 11 by ultrasonic bonding instead of using the bonding member 14b.

The insulated circuit board 11 includes an insulating plate 11a, wiring boards 11b1, 11b2, and 11b3, and a metal plate 11c. The insulating plate 11a is rectangular in plan view. The corners of the insulating plate 11a may be chamfered into rounded or beveled shapes.

The insulating plate 11a is made of a material that is electrically insulating and has superior thermal conductivity. This insulating plate 11a is made of ceramics. Example ceramics include aluminum oxide, aluminum nitride, and silicon nitride.

The wiring boards 11b1, 11b2, and 11b3 are examples of “conductive plates” for the present disclosure and are formed on the front surface of the insulating plate 11a. The wiring boards 11b1, 11b2, and 11b3 are made of a metal with superior electrical conductivity. Example metals include copper, aluminum, or an alloy containing at least one of these metals as a main component. The surfaces of the wiring boards 11b1, 11b2, and 11b3 may be plated to improve corrosion resistance. When doing so, example plating materials used here include nickel, nickel-phosphorus alloy, and nickel-boron alloy.

The wiring board 11b1 occupies the +X direction-side half of the front surface of the insulating plate 11a, and extends across the entire area from the −Y side edge to the +Y side edge. The area surrounded by the broken line indicated on the wiring board 11b1 is joined to the end (inner end portion) of the corresponding one of the first connection terminals 22a, 22b, and 22c. When doing so, the area surrounded by the broken line indicated on the wiring board 11b1 and the ends of the corresponding one of the first connection terminals 22b, and 22c may be joined via a conductive block.

The wiring board 11b2 occupies the −X direction-side half of the front surface of insulating plate 11a. This area occupied by the wiring board 11b2 extends from the +Y direction-side edge of the front surface of the insulating plate 11a to a position near the −Y direction-side edge. The area surrounded by the broken line indicated on the wiring board 11b2 is joined to the end (inner end portion) of the corresponding one of the W-phase output terminal 24a, the V-phase output terminal 24b, and the U-phase output terminal 24c. This area surrounded by the broken line indicated on the wiring board 11b2 may be joined to the corresponding one of the W-phase output terminal 24a, the V-phase output terminal 24b, and the U-phase output terminal 24c via a conductive block.

The wiring board 11b3 occupies an area surrounded by the wiring boards 11b1 and 11b2 on the upper surface of the insulating plate 11a. An end of one of the second connection terminals 23a, 23b, and 23c is joined to the area surrounded by the broken line indicated on the wiring board 11b3. This area surrounded by the broken line indicated on the wiring board 11b3 and the end of the one of the second connection terminals 23a, 23b, and 23c may be connected via a conductive block.

The metal plate 11c is formed on the lower surface of the insulating plate 11a. The metal plate 11c is rectangular in shape. In plan view, the area of the metal plate 11c is smaller than the area of the insulating plate 11a but is larger in size than the area in which the wiring boards 11b1, 11b2, and 11b3 are formed. The corners of the metal plate 11c may be chamfered into rounded or beveled shapes. The metal plate 11c is formed on the entire surface of the insulating plate 11a except for the edges. Example metals include copper, aluminum, or an alloy containing at least one of these metals. The surface of the metal plate 11c may be plated to improve corrosion resistance. When doing so, example plating materials used here include nickel, nickel-phosphorus alloy, and nickel-boron alloy.

As examples, a direct copper bonding (DCB) board or an active metal brazed (AMB) board may be used as the insulated circuit board 11 with the configuration described above. The insulated circuit board 11 may be attached to the front surface of the top plate of the cooling module 3 via a bonding member (not illustrated). Heat generated by the semiconductor chips 12 may be dissipated by being conducted to the cooling module 3 via the wiring boards 11b1 and 11b2, the insulating plate 11a, and the metal plate 11c.

The bonding members 14a and 14b may be solder. Lead-free solder is used here as the solder. As one example, lead-free solder has an alloy containing at least two of tin, silver, copper, zinc, antimony, indium, and bismuth as a main component. The solder may also contain an additive. As examples, such additive is nickel, germanium, cobalt, or silicon. By containing an additive, wettability, gloss, and bonding strength of the solder are improved, which increases reliability. As a specific example, the bonding member 14a may be sintered material. Examples of the sintered material used when bonding is achieved by sintering include powdered silver, iron, copper, aluminum, titanium, nickel, tungsten, or molybdenum.

A joining member (not illustrated) that joins the semiconductor units 10 and the cooling module 3 may be brazing material or a thermal interface material. As one example, this brazing material has at least one of an aluminum alloy, a titanium alloy, a magnesium alloy, a zirconium alloy, and a silicon alloy as a main component. Thermal interface materials include a variety of materials, such as thermally conductive grease, elastomer sheets, room temperature vulcanization (RTV) rubber, gel, and phase change materials. By attaching the semiconductor units 10 to the cooling module 3 via a brazing material or a thermal interface material, the heat dissipation performance of the semiconductor units 10 is able to be improved.

The semiconductor chips 12 include a power device element that contains silicon as a main component. The power device element is a reverse-conducting (RC)-insulated gate bipolar transistor (IGBT). An RC-IGBT has both the functions of an IGBT, which is a switching element, and a free wheeling diode (FWD), which is a diode element. The upper surface of this type of semiconductor chip 12 is provided with control electrodes 12a (such as gate electrodes) and an output electrode (emitter electrode) as a main electrode 12b. An input electrode (collector electrode) which is also a main electrode, is provided on a lower surface of the semiconductor chip 12. Note that the control electrodes 12a are provided along one side, or in the center of one side, of the upper surface of the semiconductor chip 12. The output electrode is provided in the center of the upper surface of the semiconductor chip 12.

The semiconductor chips 12 may include a switching element which is made up of a power MOSFET that has silicon carbide as a main component. This type of semiconductor chip 12 has control electrodes 12a (such as gate electrodes) and an output electrode (source electrode) as a main electrode 12b on a front surface. An input electrode (drain electrode) which is also a main electrode, is provided on a rear surface of this type of semiconductor chip 12.

The semiconductor chips 12 may also use a pair of a switching element and a diode element that each contain silicon or silicon carbide as a main component. As one example, such switching element is an IGBT or a power MOSFET. In an example configuration, this type of semiconductor chip 12 has an input electrode (drain electrode or collector electrode) as a main electrode on the rear surface, and control electrodes 12a (gate electrodes) and an output electrode (source electrode or emitter electrode) as a main electrode 12b on the front surface. The diode element may be an FWD such as an Schottky barrier diode (SBD) or a P-intrinsic-N (PiN) diode. This type of semiconductor chip 12 has an output electrode (cathode electrode) as a main electrode on the rear surface and an input electrode (anode electrode) as a main electrode on the front surface.

Lead frames 13a and 13b are provided to electrically connect the semiconductor chip 12 and the wiring boards 11b1, 11b2, and 11b3. The lead frame 13a directly connects the main electrode 12b of the semiconductor chip 12 (on the wiring board 11b2) and the wiring board 11b3 via the bonding member mentioned earlier. The lead frame 13b directly connects the main electrode 12b of the semiconductor chip 12 (on the wiring board 11b1) to the wiring board 11b2 via the bonding member mentioned earlier. The lead frames 13a and 13b may be bonded to the wiring boards 11b3 and 11b1 by ultrasonic bonding.

The lead frames 13a and 13b are made of a metal with superior electrical conductivity. Example metals include copper, aluminum, or an alloy containing at least one of these metals as a main component. The surfaces of the lead frames 13a and 13b may be plated to improve corrosion resistance. When doing so, example plating materials used here include nickel, nickel-phosphorus alloy, and nickel-boron alloy.

The control electrodes of the 12a semiconductor chips 12 of the semiconductor units 10a, 10b, and 10c housed in the unit housing portions 21e1, 21e2, and 21e3 of the frame 21 are mechanically and electrically connected to the inner end portions of the control terminals 25a, 25b, and 25c by the wires 26. The wires 26 have a material with superior electrical conductivity as a main component. Example materials include gold, copper, aluminum, or an alloy containing at least one of these metals. It is preferable for the wires 26 to be aluminum alloy containing a small amount of silicon.

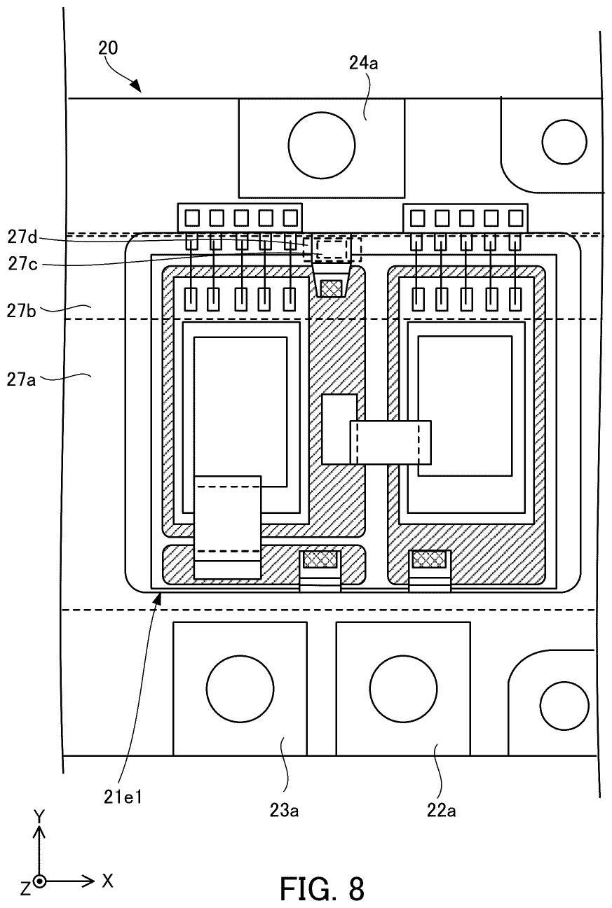

Next, the cover 27 of the housing semiconductor module 2 will be described in detail with reference to FIG. 6 to FIG. 8. FIG. 6 is a cross-sectional view (in a short-side direction) of the semiconductor device according to the embodiment, FIG. 7 is a cross-sectional view (in a long-side direction) of the semiconductor device according to the embodiment, and FIG. 8 is a plan view of a principal part of the semiconductor device according to the embodiment.

Note that FIG. 6 is a cross-sectional view taken along the dash-dotted line I-I in FIG. 1 and FIG. 2. However, the lead frames 13a and 13b and the semiconductor chips 12 of the semiconductor unit 10a have been omitted from FIG. 6. FIG. 7 is a cross-sectional view taken along the dash-dotted line I-I in FIG. 6. FIG. 8 is an enlarged plan view of the unit housing portion 21e1 of the semiconductor device 1, with the structure of the housing cover 27 that covers the unit housing portion 21e1 indicated by broken lines.

As depicted in FIG. 1, the housing cover 27 is provided from above the frame 21 and is attached to the opening 21e of the frame 21 in plan view. The housing cover 27 covers the semiconductor units 10a, 10b, and 10c that are housed in the unit housing portions 21e1, 21e2, and 21e3.

A step may be provided in the outer wall 21c-side of the unit housing portions 21e1, 21e2, and 21e3 of the frame 21. As one example, as depicted in FIGS. 6 and 7, a step 21f (see FIG. 7) that protrudes toward the unit housing portion 21e1 is provided on the outer wall 21c-side (see FIG. 6) of the unit housing portion 21e1 of the frame 21. The step 21f may be additionally provided with a pedestal 21f1 that protrudes upward from the step 21f. An example configuration where the pedestal 21f1 is provided is described here.

At the step 21f, an inner end portion of the control terminal 25a is embedded with its upper surface exposed at and flush with the step 21f. The wiring portion 24a2 of the W-phase output terminal 24a extends across the pedestal 21f1 (the step 21f) toward the unit housing portion 21e1. This wiring portion 24a2 may be parallel to the pedestal 21f1.

A lower shielding plate 28 is provided below the step 21f of the frame 21. The lower shielding plate 28 is provided inside the frame 21 so as to face a detection element 27c with the wiring portion 24a2 of the W-phase output terminal 24a in between. The lower shielding plate 28 is provided so that part of the frame 21 is sandwiched between itself and the wiring portion 24a2 of the W-phase output terminal 24a. The lower shielding plate 28 and the wiring portion 24a2 of the W-phase output terminal 24a are therefore separated and insulated from other. As each one example, the separation distance may be around 0.1 mm or more and 10 mm or less. The lower shielding plate 28 is provided so that the detection element 27c, which will be described later, does not detect magnetic fields that act as noise aside from a magnetic field produced by an output current passing through the wiring portion 24a2. The lower shielding plate 28 may have an appropriate size to shield the detection element 27c from magnetic fields that act as noise. The lower shielding plate 28 may be made of a metal that shields against magnetic fields. As examples, this metal may be copper, aluminum, iron, or an alloy containing at least one of these metals. One example of an alloy is an electromagnetic steel sheet.

Although not illustrated, the V-phase output terminal 24b, the U-phase output terminal 24c, and the control terminals 25b and 25c are also provided on the step 21f and the pedestal 21f1 of the unit housing portions 21e2 and 21e3 in the same way as the W-phase output terminal 24a. A lower shielding plate 28 is also included in the same way.

The housing cover 27 includes a cover member 27a, the wiring board 27b, the detection elements 27c, upper shielding plates 27d, and the detection output terminals 27e. The cover member 27a includes an outer surface 27a1 and the inner surface 27a2, and side surfaces (whose reference numbers are omitted) which surround the outer surface 27a1 and the inner surface 27a2 on four sides in turn. The outer surface 27a1 and the inner surface 27a2 are formed in shapes that face the opening 21e of the frame 21 in plan view. The outer surface 27a1 and the inner surface 27a2 may be substantially smooth. The cover member 27a may be made of the same material as the frame 21.

The wiring board 27b has a board surface 27b2 that faces an insulated circuit board 11 and a wiring portion 24a2. Each detection element 27c, which will be described later, is disposed on a side of the wiring board 27b that faces a wiring portion 24a2. FIG. 6 to FIG. 8 depict a configuration where a detection element 27c is disposed on the board surface 27b2 of the wiring board 27b. The wiring board 27b carries signals output from the detection elements 27c and outputs the signal from the detection output terminals 27e, which will be described later. In plan view, the wiring board 27b is rectangular in shape, as depicted in FIG. 1, and is provided on the housing cover 27 (the cover member 27a) disposed on the opening 21e, between the pair of short sides along the long edge on the outer wall 21c-side of the housing cover 27 so as to correspond to the W-phase output terminal 24a, the V-phase output terminal 24b, and the U-phase output terminal 24c. As one example, the wiring board 27b may be a printed circuit board. The wiring board 27b may be attached to the inner surface 27a2 of the cover member 27a with the board surface 27b2 facing the semiconductor units 10a, 10b, and 10c. Alternatively, the wiring board 27b may be included inside the cover member 27a with the board surface 27b2 facing the semiconductor units 10a, 10b, and 10c. The area on the board surface 27b2 where the detection elements 27c are disposed may be open and not sealed by the cover member 27a, or may be sealed. So long as the detection elements 27c are disposed on the side facing the wiring portions 24a2, the detection element 27c may be included inside the wiring board 27b.

The detection elements 27c are provided facing the upper surfaces of wiring portions respectively included in the W-phase output terminal 24a, V-phase output terminal 24b, and U-phase output terminal 24c with a gap in between. Here, the detection elements 27c are provided on the board surface 27b2 of the wiring board 27b so as to face the respective wiring portions of the W-phase output terminal 24a, the V-phase output terminal 24b, and the U-phase output terminal 24c.

Element surfaces 27c2 of the detection elements 27c face the upper surfaces of the wiring portions included in the W-phase output terminal 24a, the V-phase output terminal 24b, and the U-phase output terminal 24c, and are provided on the board surface 27b2 of the wiring board 27b. Each detection element 27c includes a conductive layer of a ferromagnetic material. This conductive layer is included in the detection element 27c and has a main surface that is parallel to the element surface 27c2. When an output current flows through the wiring portion 24a2 of the W-phase output terminal 24a toward the external connecting portion 24a3, as depicted in FIG. 7, the output current flows through the wiring portion 24a2 into the paper in FIG. 7. This output current generates a magnetic field that flows clockwise around the wiring portion 24a2. This magnetic field enters the detection element 27c across the element surface 27c2. Since the resistance of the detection element 27c will change in keeping with this magnetic field, the magnetic field may be detected based on the current flowing through the detection element 27c. The output current passes through the wiring board 27b. Such detection elements 27c may be magnetoresistive sensors. Alternatively, the detection elements 27c may be giant magnetoresistive sensors. Note that control currents passing through the control terminals 25a are very small. This means that the magnetic fields generated by control currents have hardly any effect on the detection elements 27c.

The upper shielding plate 27d is provided inside the cover member 27a so as to face the detection elements 27c with the wiring board 27b in between. The upper shielding plate 27d is provided so as to sandwich a part of cover member 27a between itself and the wiring board 27b. The upper shielding plate 27d and the wiring board 27b are therefore insulated from each other. The upper shielding plate 27d is provided so that the detection elements 27c do not detect magnetic fields that produce noise aside from the magnetic field caused by the output current passing through the wiring portion 24a2. The upper shielding plate 27d may have an appropriate size to shield the detection elements 27c from magnetic fields that act as noise. The upper shielding plate 27d may be made of the same material as the lower shielding plate 28.

Each detection output terminal 27e is provided on the outer surface 27a1 of the cover member 27a and is electrically connected through the cover member 27a to the wiring board 27b. Each detection output terminal 27e may be columnar in shape for example, and may extend vertically upward from the outer surface 27a1 of the cover member 27a. The detection output terminals 27e may be press-fit terminals. The detection output terminal 27e is made of a metal with superior electrical conductivity. Example metals include copper, aluminum, or an alloy containing at least one of these metals as a main component. The surface of each detection output terminal 27e may be plated. When doing so, example plating materials used here include nickel, nickel-phosphorus alloy, nickel-boron alloy, and tin. The current output by a detection element 27c passes from the detection element 27c through the wiring board 27b and is output from a detection output terminal 27e. The positions at which the detection output terminals 27e are disposed are not limited to the configuration in FIG. 1 and may be anywhere on the outer surface 27a1 of the cover member 27a. Note that the shape and arrangement of the wiring board 27b may be changed as appropriate in keeping with the disposed position of the detection output terminals 27e.

The semiconductor device 1 described above includes the wiring board 11b2, the case 20, and the detection elements 27c. The case 20 includes the frame 21, which surrounds the unit housing portion 21e1 that houses the wiring board 11b2 with the main surface of the wiring board 11b2 facing upward, and the W-phase output terminal 24a, which is provided in the frame 21. The W-phase output terminal 24a includes the wiring portion 24a2, which extends from part of the frame 21 to the unit housing portion 21e1, and the internal joining portion 24a1, which is integrally connected to the opposite end of the wiring portion 24a2 to the frame 21 and is connected to the wiring board 11b2. A detection element 27c is provided facing the upper surface of the wiring portion 24a2 of the W-phase output terminal 24a with a gap in between. The housing cover 27 that is provided from above the case 20 and covers the unit housing portion 21e1 is also included. The detection elements 27c are provided on the inner surface 27a2 of the cover member 27a of the housing cover 27.

As one example, when a magnetic core is used to detect an output current, the magnetic core is sometimes embedded inside the frame of a case. When attempting to miniaturize a semiconductor device of this configuration, the magnetic core will act as an obstacle to miniaturization. Alternatively, when giant magnetoresistive sensors are used to detect the output current, the sensor may be provided inside the frame or inside a semiconductor unit. In this case, the giant magnetoresistive sensors will be exposed to heat treatment during the manufacturing process of the frame or the semiconductor device, which may result in the giant magnetoresistive sensors being damaged by the heat.

On the other hand, in the semiconductor device 1, the detection element 27c is provided facing the upper surface of the wiring portion 24a2 of the W-phase output terminal 24a with a gap in between. In addition, a simple configuration where the detection element 27c is provided on the inner surface 27a2 of the cover member 27a is used. This means that even when the semiconductor device 1 is miniaturized, since the detection element 27c is provided facing the upper surface of the wiring portion 24a2 with a gap in between, this does not hinder the miniaturization of the semiconductor device 1. The detection element 27c of the semiconductor device 1 does not affect and is not affected by the manufacturing process of the semiconductor device 1. This means that the detection element 27c is not exposed to a heat treatment during the manufacturing process of the semiconductor device 1, which suppresses any decrease in the reliability of the detection element 27c.

Note that in the present embodiment, an example configuration is described where the detection elements 27c are provided for each of the W-phase output terminal 24a, the V-phase output terminal 24b, and the U-phase output terminal 24c. A detection element 27c may be provided for at least one of the W-phase output terminal 24a, the V-phase output terminal 24b, and the U-phase output terminal 24c. A detection element 27c may also be provided for at least one of the first connection terminals 22a, 22b, and 22c and the second connection terminals 23a, 23b, and 23c.

According to an aspect of the present disclosure, it is possible to provide a detection element that does not obstruct miniaturization.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a conductive plate;
a case which includes
a frame, which surrounds a housing area that houses the conductive plate with a main surface of the conductive plate facing upward, and
an external terminal provided on the frame, the external terminal including
a wiring portion that extends from a part of the frame to the housing area, and
an end portion that is integrally connected to the wiring portion and is bonded to the conductive plate; and
a detection element provided facing an upper surface of the wiring portion of the external terminal with a gap in between.

2. The semiconductor device according to claim 1, further comprising a housing cover that is provided above the case and covers the housing area,
wherein the detection terminal is provided on the housing cover.

3. The semiconductor device according to claim 2, wherein
the housing cover includes a wiring board that has a side facing the wiring portion, and
the detection element is provided on the side of the wiring board facing the wiring portion.

4. The semiconductor device according to claim 3, wherein
the housing cover has an inner surface that faces the wiring portion, and
the wiring board is provided on the inner surface of the housing cover.

5. The semiconductor device according to claim 4, wherein the case includes a lower shielding plate that is made of metal and faces the detection element with the wiring portion in between.

6. The semiconductor device according to claim 3, wherein the wiring board is shaped to have the detection terminal exposed therefrom, but is enclosed by the housing cover.

7. The semiconductor device according to claim 3, wherein the housing cover includes an upper shielding plate that is made of metal and faces the detection element with the wiring board in between.

8. The semiconductor device according to claim 3, wherein the housing cover includes a detection output terminal provided on an outer surface thereof, which is opposite to an inner surface thereof that faces the housing area, the detection output terminal being electrically connected to the wiring board through the housing cover.

9. The semiconductor device according to claim 1, wherein
the detection element includes a conductive layer, which has a main surface facing the upper surface of the wiring portion of the external terminal.

10. The semiconductor device according to claim 9, wherein the detection element is a magnetoresistive sensor.

11. The semiconductor device according to claim wherein the detection element is a giant 9, magnetoresistive sensor.

12. The semiconductor device according to claim 1, further comprising:
an insulated circuit board that is housed in the housing area, the conductive plate being an upper portion of the insulated circuit board; and
a semiconductor chip that is provided above the insulated circuit board and includes a main electrode that is electrically connected to the conductive plate.
